(19) United States
(12) Patent Application Publication
(10) Pub. No.: US 2019/0090390 A1
(43) Pub. Date: Mar. 21, 2019

(54) OBJECT-SECURABLE ELECTROMAGNETIC-SHIELDING APPARATUS

(71) Applicant: Merakai, LLC, Santa Barbara, CA (US)

(72) Inventor: Ryan Judy, Santa Barbara, CA (US)

(73) Assignee: Merakai, LLC, Santa Barbara, CA (US)

(21) Appl. No.: 15/712,105

(22) Filed: Sep. 21, 2017

(51) Int. Cl. H05K 9/00; A45C 11/32; A45C 13/10

(52) U.S. Cl. CPC H05K 9/0043; H01F 7/02; A45C 13/1069; A45C 11/32

(57) ABSTRACT

An object-securable electromagnetic-shielding apparatus provides electromagnetic-signal isolation between electromagnetic devices such as key fobs, and an ambient environment external to the apparatus. The apparatus comprises a pouch and an object securement element, and may be flexible so as to conform to the shapes of the various objects it is secured to. The apparatus may be comprised of one or more layers of electromagnetic shielding fabric, and may have a coating to protect it and devices contained therein from contaminants, corrosive substances and abrasion within the ambient environment. A shielded cavity within the pouch is accessible via a mouth portion, which in turn may be electromagnetically shielded by way of a movable closure flap. The object securement element enables the pouch to be suspendedly securable to an object in the ambient environment, and may comprise magnets disposed within lateral securement wings flexibly attached to the pouch.

### RELATED APPLICATIONS

None.

### TECHNICAL FIELD

The present invention relates generally to the field of electromagnetic shielding enclosures.

### BACKGROUND

Radio frequency (RF) shielded enclosures exist for many purposes, such as wireless testing, data security, and forensics investigations. In the conventional art, these RF enclosures possess features that are often developed for established applications. As more devices become connected, however, new applications arise which require innovative RF enclosures that fulfill niche requirements. Embodiments of the apparatus disclosed herein address market needs that have only become apparent recently.

By way of example, in recent years, the auto industry has seen an influx of “smart” key fobs, a type of vehicle key that can unlock, start, and perform other operations on a vehicle without human interaction, often by simply being within close proximity to the vehicle. Although convenient, this feature has opened a new set of problems for vehicle dealerships, auto body shops, mechanics, or any individual associated with vehicle maintenance, as well as the general public. Smart key fobs allow a vehicle to not only unlock when in close proximity, but to start without a traditional physical key in the ignition. This presents a major concern for anyone performing servicing on a vehicle. For example, if a car were to be void of oil during an oil change, an accidental start could destroy the engine, severely or fatally injure the mechanic, and potentially even injure the customer. As more and more vehicles are designed with smart key fobs, the need for a key fob RF shielding solution becomes significant. While many conventional RF enclosures could shield the signal from the key fob, none have been developed with the unique set of features to truly meet the needs of this application, or other applications with similar requirements.

### SUMMARY

Certain deficiencies of the prior art may be overcome by the provision of one or more embodiments of an object-securable electromagnetic-shielding apparatus. The preferred embodiments of the apparatus disclosed herein (also referred to herein as an “enclosure”) may be particularly advantageous for use by mechanics and auto body shop employees. However, they may also be advantageously used by vehicle manufacturers, professional valet services, office parking services, car rental companies, general consumers, and anyone looking to signal-isolate their smart key fobs from their vehicles.

Embodiment of the apparatus may be portable, quick to open and close, and high-shielding to ensure signal blockage. The enclosure apparatus may include “wings” on both sides with, for example, magnets, to allow the enclosure to attach to any flat or irregular surface. The wings may protrude laterally from the sides to allow the enclosure to conform to rounded, irregular, or odd shaped surfaces, which are often encountered in locations designed for certain preferred applications of the apparatus.

A closure flap may include magnets as well, to allow the apparatus to seal completely and easily, but also to allow it to stay open against a magnetic surface when, for example, the closure flap is articulated upward. A supplemental section of conductive fabric above the fold line of the closure flap may be designed to maintain conductive contact even around bulky devices such as large keysets

Embodiments of the presently-disclosed apparatus may be constructed with malleable materials to allow for varying dimensions of contents inside. The shape of the apparatus may be manipulated to adhere to irregular surfaces, such as corners and rounded sides of objects to which the apparatus is suspendedly secured. The apparatus is portable, lightweight and small in size to allow a user to easily move it from one location to another, while keeping devices inside shielded.

Certain preferred embodiments of the apparatus may be soft-sided, flexible, high-shielding, and durable. The outside may include a polymer (e.g., rubberized or PVC) coating or shell which protects the entire exterior, and even parts of the interior cavity, from dirt, oil, water and other contaminants or corrosives commonly found in or around vehicles and vehicle servicing environments. Moreover, the coating may prevent an external object from becoming damaged by the devices placed within the apparatus. Such coating may also allow contaminants to be easily wiped off of the apparatus, and may be thick and tough enough to protect the apparatus and surrounding objects against friction and scratches.

### BRIEF DESCRIPTION OF THE DRAWINGS

Further advantages of the present invention may become apparent to those skilled in the art with the benefit of the following detailed description of the preferred embodiments and upon reference to the accompanying drawings in which:

FIG. 1 is a diagrammatic front view of one example embodiment of an object-securable electromagnetic-shielding apparatus, with a closure flap shown in a closed position;

FIG. 2 is a diagrammatic front view of an embodiment similar to that of FIG. 1, but wherein the closure flap in an open position;

FIG. 3 is a diagrammatic partial perspective view of an embodiment similar to that of FIG. 1, but wherein the closure flap is shown in the process of being manually moved from a closed position to an open position;

FIG. 4 is a diagrammatic perspective view of an embodiment similar to that of FIG. 1, but wherein the mouth portion of the pouch element is shown manually retained in an open configuration and the flap portion is shown in an open position;

FIG. 5 is a diagrammatic perspective view of an embodiment similar to that of FIG. 1, but with the apparatus shown suspendedly secured about the corner of an object such as a metal wall or pillar;

FIG. 6 is a diagrammatic perspective view similar to that of FIG. 5, but with the apparatus shown suspendedly secured about a rounded cylindrical metal object;

FIG. 7 is a diagrammatic perspective view of an example embodiment of an object-securable electromagnetic-shielding apparatus, showing the apparatus suspendedly secured to a horizontal beam object and providing electromagnetic-signal isolation between a transmitting electromagnetic key fob device and an ambient environment external to the apparatus in which a corresponding vehicle resides in close proximity to the key fob;

FIG. 8 is a diagrammatic rear view of the embodiment shown in FIG. 2 with the closure flap in an open position;

FIG. 9 is a diagrammatic front view of an embodiment similar to that shown in FIG. 1, but wherein the object securement element includes multiple eyelets with central apertures extending through respective securement wings;

FIG. 10 is a diagrammatic cross-sectional view of an apparatus similar to that shown in FIG. 2, with the closure flap in an open position; and

FIG. 11 is a diagrammatic cross-sectional view of an apparatus similar to that shown in FIG. 1, with the closure flap magnetically secured in a closed position.

### DETAILED DESCRIPTION OF THE PREFERRED EMBODIMENTS

Referring now to the drawings, like reference numerals designate identical or corresponding features throughout the several views.

Example embodiments of an object-securable electromagnetic-shielding apparatus are shown generally at 100. Embodiments of apparatus 100 may be particularly adapted for providing electromagnetic-signal isolation between electromagnetic devices (such as, for example, a key fob 102 or other remote keyless system) and an ambient environment 106 external to the apparatus 100. Accordingly, the apparatus 100 may prevent transmission of electromagnetic signals from a device 102 from undesirably reaching a corresponding signal receiver 108 (for example, in a vehicle 110) which is in close proximity to the device 102. With respect to certain preferred embodiments of the apparatus 100, the term “close proximity” may mean within 20 meters.

Embodiments of the apparatus 100 may preferably comprise at least a pouch element 112 and at least one object securement element 120. The pouch element may include a pouch cavity 114 defined therein, a front panel 142, a rear panel 144, and a mouth portion 118. The pouch cavity 114 may be at least partially enveloped by electromagnetic shielding material. For example, the pouch element 112 may be principally or largely constructed of such material.

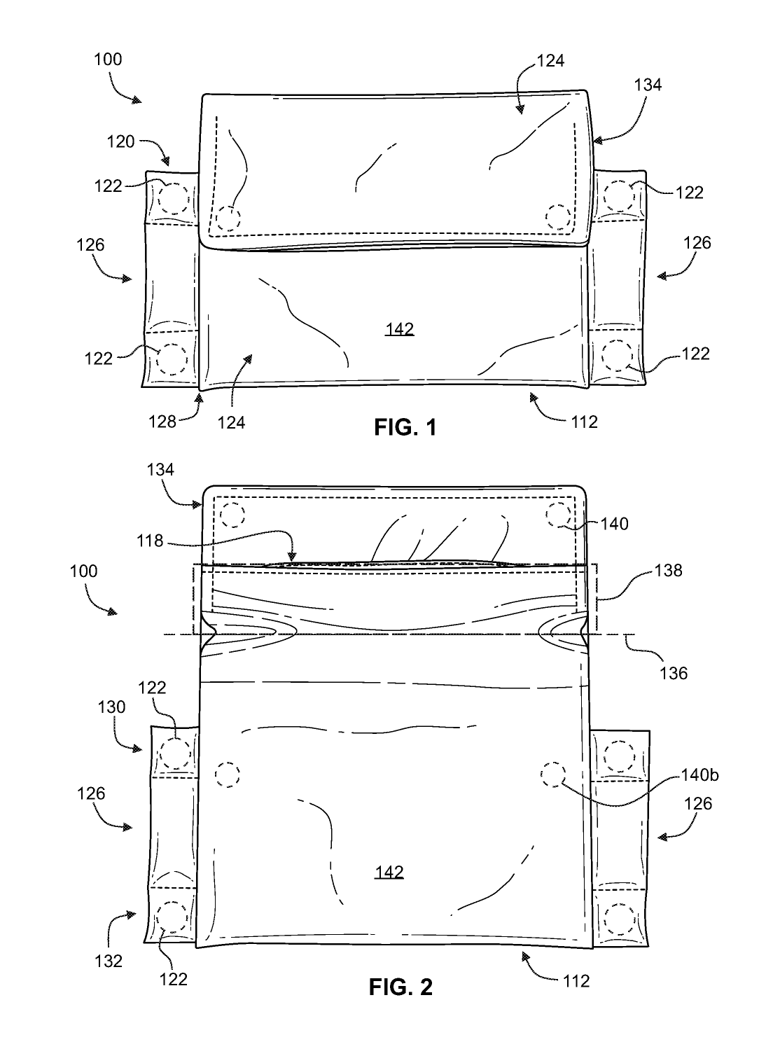

The mouth portion 118 may have an open configuration (see, for example, FIG. 2) and a closed configuration (see, for example, FIG. 1). Referring to FIG. 4, in certain preferred embodiments, the mouth portion 118 allows passage of a vehicle RF key fob device 102 into and out of the pouch cavity 114 when in the open configuration, and blocks passage of a vehicle RF key fob device 102 into and out of the pouch cavity when in the closed configuration. By way of example, a typical vehicle key fob device may be 1-3 inches in length, 1-2 inches in width and 0.5-1 inches thick.

The pouch element may be suspendedly securable to an object 104 in the ambient environment 106 by way of the object securement element(s) 120. For example, an object securement element 120 may include one or more object securement magnets 122.

In particular embodiments, the pouch cavity 114 may be electromagnetic-signal isolated from the ambient environment 106 when the mouth portion 118 is in the closed configuration. For example, the electromagnetic-signal isolation may be achieved merely by closure of the mouth portion 118, irrespective of the inclusion or position of a closure flap 134.

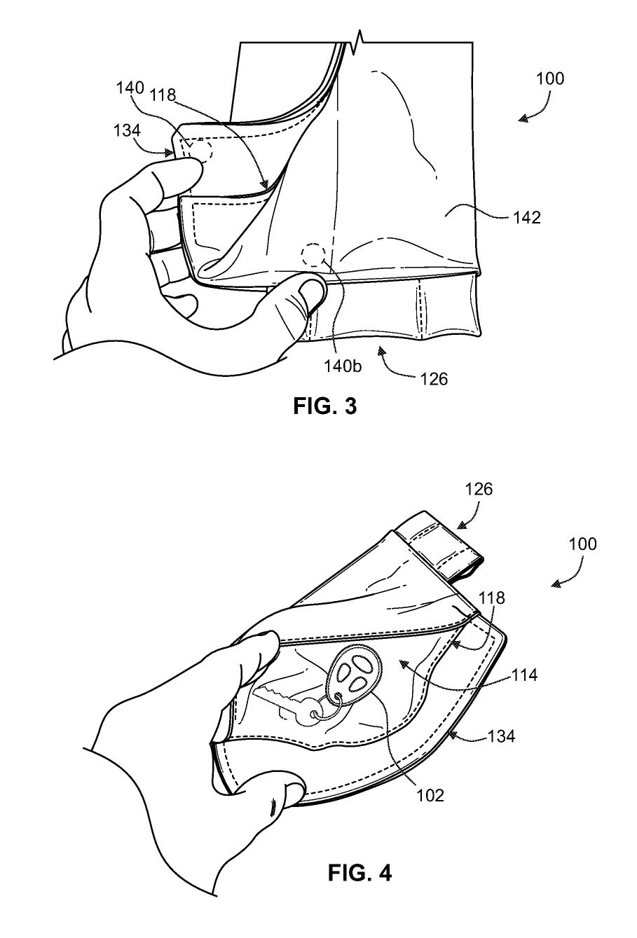

In typical preferred embodiment of the apparatus 100, such as those shown in FIGS. 3-6, the pouch element 112 is flexible. Moreover, the apparatus 100 may preferably include an external surface 124 with a flexible polymer coating thereon. The flexible polymer coating may comprise, for example, PVC or the like.

Referring to FIGS. 1 and 5-7, certain embodiments of the apparatus 100 may include one or more securement wings 126 by which the suspended securability is achieved. The one or more securement wings 126 may support or house respective object securement magnets 122. In particular embodiments of the apparatus 100, a pair of securement wings 126 may be disposed on opposing sides of the pouch element 112. The securement wings 126 may each be flexibly connected to the pouch element 112, thereby defining, for example, a flex joint 128. Referring to FIG. 2, each of the securement wings 126 may include a pair of object securement magnets 122 disposed at opposing ends (e.g., 130 and 132) of the respective securement wing 126.

Particular preferred embodiments of an object-securable electromagnetic-shielding apparatus may include a closure flap 134 hingedly connected to or foldably associated with the pouch element and configured to be moved between closed and open positions. The closure flap 134 may be at least partially comprised of electromagnetic shielding material. In such cases, when the closure flap 134 is in the closed position, the mouth portion 118 is RF-shielded from the ambient environment 106. When the closure flap 134 is in the open position, the mouth portion may not be RF-shielded from the ambient environment 106.

In certain preferred embodiments of the apparatus 100, the closure flap 134 may include one or more flap securement elements 140. The flap securement elements 140 may be, for example, flap securement magnets. In such embodiments, the closure flap may be magnetically securable to the front panel 142 when in the closed position, and thereby magnetically releasably retained in the closed position. Moreover, when the closure flap 134 is in the open position, the closure flap 134 may be magnetically securable to the object 104 (e.g., to which the apparatus 100 is suspendedly secured) for retaining the closure flap 134 in the open position.

Electromagnetic-shielding material used in the construction of the apparatus 100, including in one or more of the pouch element 112, closure flap 134, and securement wings 126, may be referred to as “Faraday fabrics.” Such fabrics may comprise, for example, a conductive fiber with a weave. In certain preferred embodiments, the fabric may be composed of, for example, a blend of polyester fiber (e.g., 62%+/−7%), metallic copper (e.g., 25%+/−7%) and metallic nickel (e.g., 13%+/−7%). The conductive fiber may have a thickness, for example, of 0.08 mm+/−0.02 mm. In particular embodiments, silver may be used in the fiber blend shielding material as a conductive constituent, either to supplement or in place of the copper and nickel constituents. The electromagnetic-shielding material may include a Polyvinyl Chloride (PVC) resin coating or the like.

FIG. 2, illustrates a front view of a preferred embodiment of the apparatus 100 with the closure flap 134 raised to open position and securement wings 126 expanded laterally outward. Contents, such as electromagnetic devices 102, may be introduced into the pouch cavity 114 of the apparatus 100 through the mouth portion 118. An outer coating or layer, such as PVC, may be present on the external surface 124 of the apparatus 100. Such coating may be, for example, lightweight, durable, flexible, water-resistant, contaminant-resistant, and possibly rubberized. Other protective materials may be implemented on the outside of the apparatus 100, such as plastic, tarpaulin, or any other material capable of protecting the apparatus 100 from contaminants or corrosives present in the ambient environment.

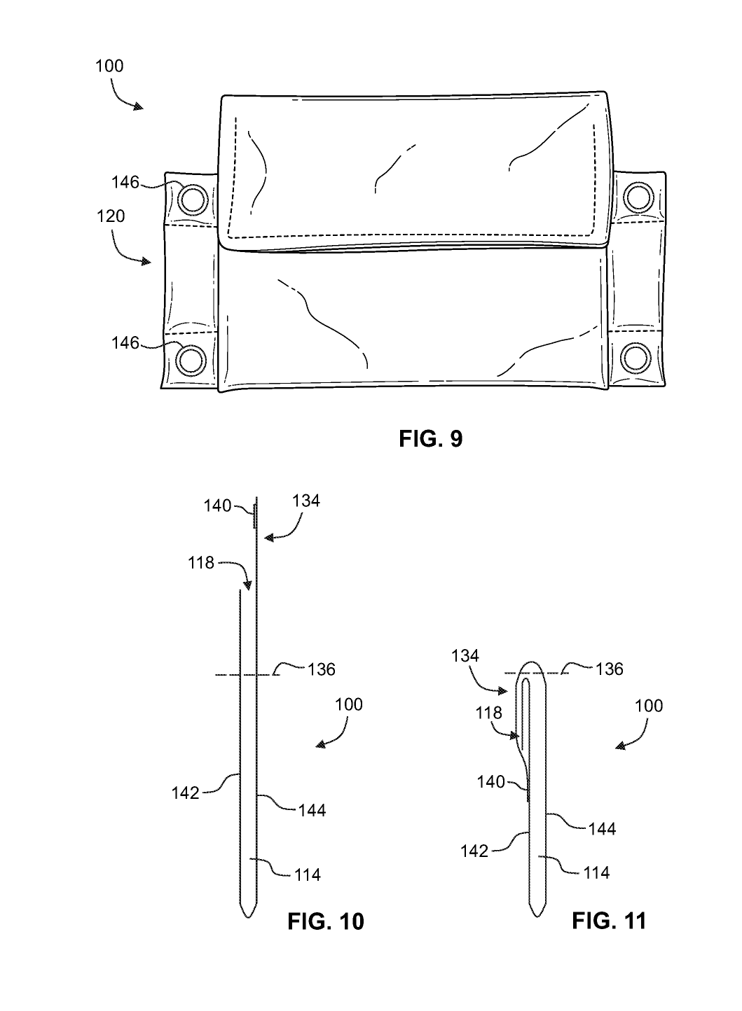

The closure flap 134 may be held up and in an open position by, for example, flap securement magnets 140 in the top corners so as to adhere to the object 104 to which the apparatus 100 is suspendedly secured (e.g., a metal surface or the like). The securement wings 126 may be expanded and securely held against the object 104 (e.g., a metal surface thereof) by object securement magnets 122 sewn into the apparatus 100 in various locations, including inside the ends (130 and 132) of the securement wings 126, the corners of the closure flap 134, and even lateral connection points defined along the fold line 136 where the closure flap 134 folds over to seal the mouth portion 118. Additionally, or in the alternative, other means of removably securing the apparatus 100 to a surface of an object 104 may be incorporated into the apparatus 100, such as holes (e.g., eyelets 146 in FIG. 9), grommets, hooks, hook and loop fasteners, a combination thereof or the like. Securement wings 126 may or may not be present, depending upon the embodiment.

FIG. 1 illustrates a front view a preferred embodiment of the apparatus 100 with the closure flap 134 in a closed position. In such embodiment, the closure flap 134 may be securely held shut by magnet connection. In alternative embodiments, the method the closure flap may be securable in a closed position by hook and loop fastener, snaps, or any other means of securing the closure flap 134 in the closed position (e.g., against the front panel 142 of the apparatus 100. In yet further embodiments, a closure flap 134 may not be used. Rather, such further embodiments may provide a cinch strap, a roll, a door, an elastically-biased lip around the mouth portion 118, or some other means of reliably and reversibly sealing the pouch cavity 114 from passage of electromagnetic signals 116 (e.g., to maintain an RF-tight seal).

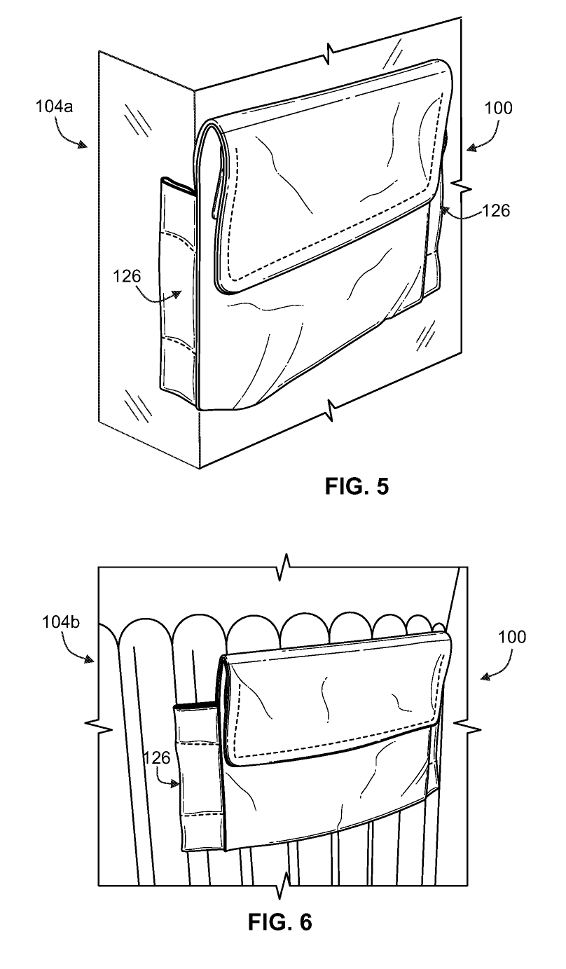

FIG. 5 illustrates an embodiment of the apparatus 100 adhering (suspendedly secured) to a right angle of an object 104a by wrapping around a corner of the object. The ability to attach to irregular surfaces, particularly those comprised of metal, is a feature that renders the apparatus 100 uniquely compatible with various surfaces such as work booths, podiums, racks, shelves, the car itself, and kiosk stations used in auto body and vehicle maintenance shops. Preferred embodiments of the apparatus 100 allow for effortless removal, transport, and reattachment of the RF enclosure and subsequently the keys inside of it.

FIG. 6 illustrates an embodiment of the apparatus 100 adhering to a curved metal object 104b such as a corrugated metal barrel. The securement wings 126 with object securement magnets 122 also help stabilize the apparatus 100 on the object 104b vertically and rotationally, thus preventing it from undesirably rotating or sliding along the surface of the object 104b. This figure illustrates the ability of embodiments of the apparatus 100 to conform to (e.g., wrap around) irregular surfaces to which the apparatus 100 is suspendedly secured.

FIG. 8 illustrates the backside of an embodiment of the apparatus 100 with the closure flap 134 in its open position. Preferred embodiments of the apparatus 100 may uses a rubberized or otherwise elastic coating (e.g., PVC) throughout the external surface 124 of the apparatus and along the inside surface of the closure flap 134. This coating may be resistant to contaminants and abrasion. The shielding material inside the apparatus 100 may be susceptible to damage from corrosion, abrasion, and deterioration, which is a significant concern within a service shop environment, such as an automotive service area. The outer durable material may protect the shielding liner inside from exposure to damaging elements in the environment such as dirt, grease, chemicals, and even friction. The outer material may also protect external surfaces from damage from the materials in the enclosure itself. For example, it may be desirable to attach the apparatus 100 to the side of a vehicle during service, or perhaps in other applications such as consumer home use. The abrasion-resistant coating materials prevent magnets and other components or devices within the apparatus 100 from damaging the surface of the vehicle. In alternate embodiments of the apparatus, other coatings or outer materials may be used, such as plastic, tarpaulin, waterproof vinyl, or the like.

Referring to FIG. 4, the mouth portion 118 may be manually expandable to a size large enough for hands to easily and rapidly insert or remove a keyset. The volume of the pouch cavity 114 may allow for a large keyset with accessories. In the embodiment illustrated, the structure of the apparatus 100 may be sufficiently flexible so as to encompass keysets of various sizes while still being able to wrap around curved, angled, or irregular shaped object surfaces. The inner shielding liner may be made with three layers of RF signal blocking fabric on each side which make complete mutual contact at the mouth portion 118 when the mouth portion is in closed configuration and the closure flap 134 is folded over in its closed position. In further embodiments, more or fewer layers of shielding fabric may be used. In further alternative, certain embodiments may not use shielding fabric, but instead may incorporate conductive plates, continuous conductive metal, shielded foam, or any other material that provides RF shielding.

Referring to FIG. 3, in certain embodiment of apparatus 100, when the closure flap 134 is folded over and closed, the compartment (e.g., pouch cavity 114) becomes signal isolated thus preventing a key fob or other device 102 held inside from communicating with a vehicle 110. If anything impedes the connection point, or the seal is not perfect in any way, RF shielding may be compromised. In the illustrated embodiment, the user opens the enclosure by pulling upward on the closure flap 134 and closes the enclosure by folding the top of closure flap 134 over and connecting flap securement magnets 140 on the closure flap 134 to another set of magnets 140b on the front mid-section of front panel 142 of the enclosure. Magnets may provide a preferred and rapid method of opening and closing the apparatus 100. However, in alternate embodiments, other methods to secure the closure flap 134 in closed position may be used such as hook and loop, elastic, buttons, a combination thereof or the like.

Referring again to FIG. 2, the illustrated embodiment may include a section of conductive fabric (e.g., within the zone of supplemental shielding fabric 138) above the flap fold line 136. This extra section may increase the shielding effectiveness of the apparatus 100 by ensuring that bulky devices placed inside the pouch cavity 114, such as keys, do not push the front panel 142 and rear panel 144 apart so as break the electromagnetic seal across the mouth portion 118. This extra section of fiber may maintain conductive contact beyond the point of the fold, thereby ensuring that shielding failure does not occur at or around the mouth portion 118 during use of the apparatus 100.

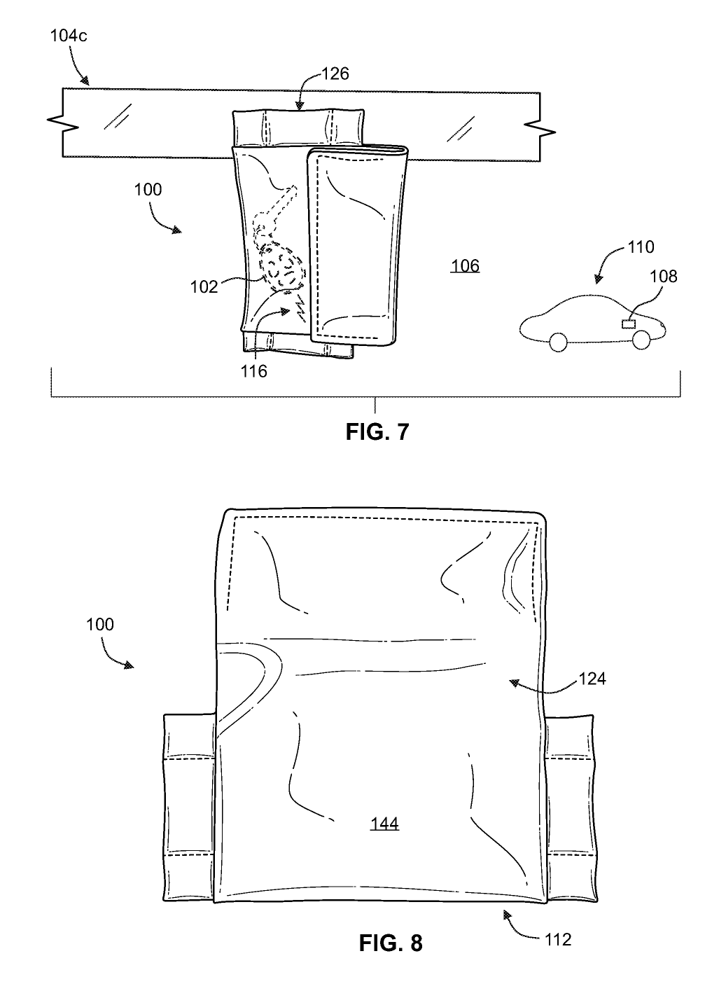

Referring to FIG. 7, the securement 126 wings may be constructed with high-strength magnets 122 (e.g., neodymium magnets) sewn into the corners. The illustrated embodiment may include strong enough object securement magnets 122 to support the apparatus 100, as well as devices 102 inside, with only a single securement wing 126 attached to an object 104c surface at one time. Another purpose of high-strength magnets may be to allow the apparatus 100 to adhere to semi-magnetic surfaces, which may be difficult to adhere to using low-strength magnets. Future embodiments may have greater or fewer magnets in alternate placements, or may not rely on magnets at all to attach the apparatus to external surfaces. Moreover, object securement magnets 122 may be sewn into each corner (e.g., ends 130 and 132) of the securement wing 126, while the middle portion in between may remain empty. The lack of connection in the middle may allow a user to easily pull the enclosure away from a metal surface with reduced resistance or stress being applied to seams of the apparatus 100.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. An object-securable electromagnetic-shielding apparatus for providing electromagnetic-signal isolation between electromagnetic devices and an ambient environment external to the apparatus, the apparatus comprising:
a pouch element including a pouch cavity and a mouth portion, the pouch cavity being at least partially enveloped by electromagnetic shielding material, the mouth portion having an open configuration and a closed configuration; and
an object securement element by which the pouch element is suspendedly securable to an object in the ambient environment, the object securement element including one or more object securement magnets.

2. An object-securable electromagnetic-shielding apparatus as defined in claim 1, wherein the mouth portion
(a) allows passage of a vehicle RF key fob device into and out of the pouch cavity when in the open configuration; and
(b) blocks passage of a vehicle RF key fob device into and out of the pouch cavity when in the closed configuration.

3. An object-securable electromagnetic-shielding apparatus as defined in claim 1, wherein the pouch cavity is electromagnetic-signal isolated from the ambient environment when the mouth portion is in the closed configuration.

4. An object-securable electromagnetic-shielding apparatus as defined in claim 1, wherein the pouch element is flexible.

5. An object-securable electromagnetic-shielding apparatus as defined in claim 1, wherein the apparatus includes an external surface with a flexible polymer coating thereon.

6. An object-securable electromagnetic-shielding apparatus as defined in claim 1, wherein the apparatus includes one or more securement wings by which the suspended securability is achieved.

7. An object-securable electromagnetic-shielding apparatus as defined in claim 6, wherein the one or more securement wings house respective said one or more object securement magnets.

8. An object-securable electromagnetic-shielding apparatus as defined in claim 6 including a pair of said securement wings disposed on opposing sides of the pouch element.

9. An object-securable electromagnetic-shielding apparatus as defined in claim 8 wherein the securement wings are each flexibly connected to the pouch element.

10. An object-securable electromagnetic-shielding apparatus as defined in claim 6, wherein each of the securement wings includes a pair of said object securement magnets disposed at opposing ends of the respective securement wing.

11. An object-securable electromagnetic-shielding apparatus as defined in claim 1, including a closure flap foldably associated with the pouch element and configured to be moved between closed and open positions, wherein,
(a) the closure flap is at least partially comprised of electromagnetic shielding material;
(b) when the closure flap is in the closed position, the mouth portion is RF-shielded from the ambient environment; and
(c) when the closure flap is in the open position, the mouth portion is not RF-shielded from the ambient environment.

12. An object-securable electromagnetic-shielding apparatus as defined in claim 11, wherein the closure flap includes one or more flap securement magnets.

13. An object-securable electromagnetic-shielding apparatus as defined in claim 12, wherein
(a) the pouch element includes a front panel and a rear panel; and
(b) the closure flap is magnetically securable to the front panel when in the closed position.

14. An object-securable electromagnetic-shielding apparatus as defined in claim 13, wherein when the closure flap is in the open position the closure flap is magnetically securable to the object for retaining the closure flap in the open position.

15. An object-securable electromagnetic-shielding apparatus for providing electromagnetic-signal isolation between electromagnetic devices and an ambient environment external to the apparatus, the apparatus comprising:
(a) a pouch element including a pouch cavity and a mouth portion, the pouch cavity being at least partially enveloped by electromagnetic shielding material, the mouth portion having an open configuration and a closed configuration;
(b) an object securement element by which the pouch element is suspendedly securable to an object in the ambient environment; and
(c) a closure flap foldably associated with the pouch element and configured to be moved between closed and open positions, wherein,
(i) the closure flap is at least partially comprised of electromagnetic shielding material;
(ii) when the closure flap is in the closed position, the mouth portion is electromagnetic-shielded from the ambient environment;
(iii) when the closure flap is in the open position, the mouth portion is not electromagnetically-shielded from the ambient environment;
(iv) the closure flap includes one or more flap securement magnets;
(v) the pouch element includes a front panel and a rear panel;
(vi) the closure flap is magnetically securable to the front panel when in the closed position; and
(vii) when the closure flap is in the open position the closure flap is magnetically securable to the object for retaining the closure flap in the open position.

16. An object-securable electromagnetic-shielding apparatus as defined in claim 15, wherein the mouth portion
(a) allows passage of a vehicle RF key fob device into and out of the pouch cavity when in the open configuration; and
(b) blocks passage of a vehicle RF key fob device into and out of the pouch cavity when in the closed configuration.

17. An object-securable electromagnetic-shielding apparatus as defined in claim 15, wherein the apparatus includes one or more securement wings by which the suspended securability is achieved.

18. An object-securable electromagnetic-shielding apparatus as defined in claim 17, wherein each of the securement wings houses one or more object securement magnets therein.

19. An object-securable electromagnetic-shielding apparatus as defined in claim 15, wherein the apparatus includes a flexible polymer coating.

20. An object-securable electromagnetic-shielding apparatus as defined in claim 19, wherein the flexible polymer coating is comprised of PVC.
